(19) United States
(12) Patent Application Publication
(10) Pub. No.: US 2010/0131216 A1
(43) Pub. Date: May 27, 2010

(54) Power curve of wind power plant for energy network

(75) Inventor: Bernt Ebbe Pedersen, Kolding (DK)

Correspondence Address: Mollborn Patents, Inc., 2840 Colby Drive, Boulder, CO, 80305, US

(73) Assignee: LM GLASFIBER A/S, Kolding (DK)

(21) Appl. No.: 12/597,777

(22) PCT Filed: Apr. 16, 2008
(86) PCT No.: PCT/DK08/00141

§ 371 Date: Nov. 13, 2009

(30) Foreign Application Priority Data
Apr. 27, 2007 (DK) PA2007/00626

(51) Int. Cl. G01R 21/00; G06F 19/00

(52) U.S. Cl. 702/60; 702/3

(57) ABSTRACT

The invention relates to a method of determining a desired power curve for a wind power plant for use in connection with the subsequent design and positioning of the wind power plant (307), where the wind power plant is to be coupled as energy source to a power network comprising a number of energy sources. The power curve is determined relative to the remaining energy sources of the power network to the effect that the power supply of the wind energy plant is maximised during periods (203) when the total power output (301) from the remaining energy sources of the power network is low. The invention further relates to a system of determining a desired power curve for a wind power plant. The invention also relates to a group of energy sources comprising a wind power plant and a number of remaining energy sources, where the power curve of the wind power plant is such that power supply is maximised in periods of time (203) when the total power output from the remaining sources of energy is low.

### BACKGROUND

An energy network, such as an electrical power network that regulates and provides services to the energy supply of a region, is described in general by its local energy sources such as e.g. coal-fired, hydro-, nuclear power plants, wind power farms, its consumers and the associated transmission capacities, both internally in the network and in and out of the network for importation and exportation of power. Conventionally, the various energy networks are bound to countries, regions or areas of land, but often they are also defined by geographical or purely practical conditions. One example of such geographically delimited power network is western Denmark which is currently electrically connected to Norway, Sweden, and Germany. The overall transmission capacity to Norway constitutes 1040 MW, while the overall capacity to Sweden constitutes 740 MW. Finally, there are the connections to Germany that have an overall capacity in the southbound direction (i.e. exportation from western Denmark) of about 1250 MW. The overall transmission capacity out of western Denmark thereby constitutes about 3000 MW. Besides, a 600 MW connection under the Great Belt is planned.

As time goes by, the connections (both the purely physical transmission cables and the political and financial cooperation) between the individual areas become increasingly improved to the effect that the individual areas and power networks are increasingly interrelated with ensuing advantages and drawbacks of such interrelation. Thus, a well upgraded transmission network is essential for ensuring a stable energy supply with good options for both importation and exportation, depending on what can be advantageous both with respect to price and production, whereas, conversely, a sudden local failure in e.g. Holland may, in a worst-case scenario, also entail power cuts in the major part of Europe. The control and regulation of the individual power networks are therefore of the utmost importance. In the majority of cases, it is therefore a priority to power networks to strike a balance between energy generation and consumption to avoid operating failures both in the form of potential power cuts in case of too low production and to avoid electricity spill-over in case of excess production which may ultimately lead to complete failure of the power network. The energy generation in the power network is therefore continuously upscaled and downscaled to the extent possible in pace with prognoses on consumption and expectations for importation and exportation.

In 2006, the installed wind turbine power in western Denmark constitutes about 2400 MW and thus constitutes a considerable part of the energy production. The replacement of old wind turbines with more recent and larger turbines is furthermore expected to contribute with further 175 MW by the end of 2009. Moreover, the sea-based wind farm Horns Rev 2 is to be put into operation in 2009, which adds further 200 MW. Finally, based on a national Danish energy plan and for the EU, a considerably more intense growth is expected which presumably entails a doubling of the installed wind turbine power output capacity within the next approximately 15 years, not merely in western Denmark, but also in Europe. It is generally desired in many places to increase the wind power output based on the views that wind power is a sustaining and environmentally friendly source of energy which is omnipresent and hence able to contribute to making, to a higher degree, the energy supply of each individual region independent any import of oil, coal, and gas. Where, earlier on, the wind power was produced by singular or a small number of individual interconnected wind power plants, now, most often large groups of wind power plants are deployed or even decided wind farms that can be coupled directly to the power network. New wind power plants and groups of wind power plants are conventionally designed to yield the largest possible annual power output, and, in recent years, development has moved towards increasingly larger wind power plants with longer blades, more sophisticated power control and larger power output.

However, a fairly significant drawback of wind power is that the production is directly condition by and varies considerably with the current wind and weather conditions. Therefore, it is necessary that the wind power generation is a supplement to conventional sources of energy whose power outputs are consequently to a certain extent to be upscaled and downscaled in pace with the produced amount of wind power, expected consumption and prognoses of same, e.g. based on weather forecasts.

However, it is a both complex and resource-intensive process to up- and down-scale the power output of the power plants, which takes both comparatively long time (several hours) and causes undue wear on the installations of the power plants. This is a problem in particular in the context of coal-fired and nuclear power plants.

A further problem of expanding the wind power generation in a power network is that the power output will be considerably increased in case of the elevated wind speeds, where all the wind power plants (however with minor regional differences) will produce maximally independently of the current consumption and need as such or options for exportation. Thus the power network must be dimensioned to be able to handle and cope with such peak loads to avoid power failures, which requires is large transmission capacity. An expansion of the wind power capacity in Denmark as expected, where the overall transmission capacity out of western Denmark constitutes, as mentioned, about 3000 MW or just slightly more than the overall installed wind turbine power output today, will thus necessitate an investment in the range of DKK 12 billion for larger or newer transmission lines to enable sufficient exportation. An alternative to this is to control the power output of each individual wind farm such that it does not exceed a certain maximum value—either by gradual reduction of the power generation of each wind power plant or by completely stopping individual turbines in the wind farm, as described e.g. in U.S. Pat. No. 6,724,097 (Wobben). The drawbacks of this strategy is, on the one hand, that it necessitates a complex control of each group of wind power plants and, on the other, that one misses out on a considerable amount of power.

Another relevant aspect of significance to the expansion of the wind power output is the price on power which is, in the Nordic countries, determined on the Nordic electricity exchange. There the price on power is set 24 times per calendar day, on the day before the working calendar day, based on supply and demand on the overall market (the system price). Owing to limitations in the transmission capacity and the fact that current cannot readily be stored, the so-called area price is determined in the individual regions which depends on supply and demand in the individual region and, of course, on the transmission options. In areas where wind turbines cover a considerable part of the electricity consumption, the area price will be influenced by the wind speed, since increasing wind speed entails a dramatically increasing supply of electricity. For instance, the area price in Jutland is sometimes as low as DKK 0.01/kWh on windy nights. This type of area is expected to become more widespread in the future in pace with increasing expansion of the wind power capacity and optionally increasing liberalisation of the electricity markets. An expansion of the installed wind power capacity alone can thus be expected to enhance the above-described tendency to the effect that the earning capacity of a wind power plant is deteriorated.

### OBJECT AND DESCRIPTION OF THE INVENTION

It is the object to provide a solution to the above problems.

This is accomplished by a method of determining a desired power curve for a wind power plant for use in connection with subsequent design and positioning of the wind power plant, where the wind power plant is to be connected as source of energy to a power network comprising a number of energy sources. The power curve is determined relative to the remaining energy sources of the power network to the effect that the power supply of the wind power plant is maximised in periods of time with low overall power output from the remaining energy sources of the power network.

Thereby a more even power supply to the power network is accomplished.

According to one embodiment, wind and weather data for the determined periods in time are used in connection with the determination of the power curve. Precisely wind and weather data are of major significance in the determination of the power curve for a wind power plant.

According to one embodiment wind and weather data are collected for the geographic position, where it is intended to deploy a wind power plant. Thereby data are available that can enable one to find a power curve for a wind power plant that is to be deployed in precisely that geographical position.

According to one embodiment wind and weather data are collected for a number of geographic positions. Thereby one may also use the position as a parameter in connection with the design/selection of wind power plant relative to a desired power curve.

According to one embodiment it is determined whether the overall power output from the remaining power sources of the power network is low based on a predefined threshold value. This is a particularly simple way in which to identify the low periods.

Besides, the invention relates to a system for determining a desired power curve for a wind power plant for use in connection with subsequent design and positioning of the wind power plant, where the wind power plant is to be coupled as a source of energy to a power network comprising a number of power sources, said system comprising:
means for measuring and collecting the total power output from the remaining energy sources of the power network as a function of time;
means for identifying periods of time when the total power output from the remaining energy sources of the power network is low;
means for determining a desired power curve based on the identified periods of time.

Also, in a particular embodiment, the invention relates to means for collecting wind and weather data for the determined periods of time.

The invention further relates to a group of energy sources comprising a wind power plant and a number of remaining energy sources, where the power curve of the wind power plant is such that power supply is maximised in periods of time when the total power output from the remaining sources of energy is low.

### BRIEF DESCRIPTION OF DRAWINGS

In the following, the invention will be described with reference to the figures, in which

FIG. 1 is an illustration of a power supply net;

FIG. 2 shows an example of a total power output over time of the sources of energy to the power network;

FIG. 3 shows the principle behind a method of determining a desired power curve for a wind power plant for being coupled to an existing power network;

FIG. 4 shows a method of determining a desired power curve for a wind power plant for being coupled to an existing power network;

FIG. 5 shows a method of determining a desired power curve for a wind power plant for being coupled to an existing power network;

FIG. 6 shows a method of determining a desired power curve for a wind power plant for being coupled to an existing power network;

FIG. 7 shows a wind power plant and a determined desired power curve.

### DESCRIPTION OF EMBODIMENTS

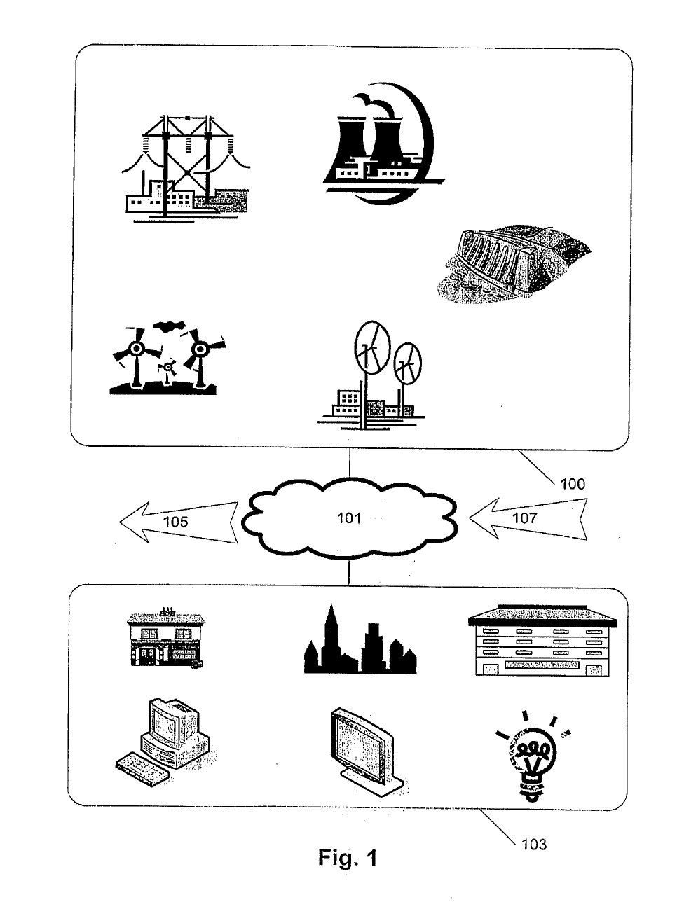

FIG. 1 shows an example of a power network in the shape of an electricity network (101) comprising energy sources (100) and consumers/buyers of energy (103). “Energy sources” (100) is a collective designation for a number of different sources of energy such as coal-fired, hydro- and nuclear power plants, wind farms, etc. that all supply energy to the power network; and “energy buyers” (103) is a collective designation for a number of different consumers of energy, such as cities, factories, and households comprising electrical apparatuses. Moreover, it is possible to export (105) from the power network (101), and it is possible to import (107) energy to the power network (101).

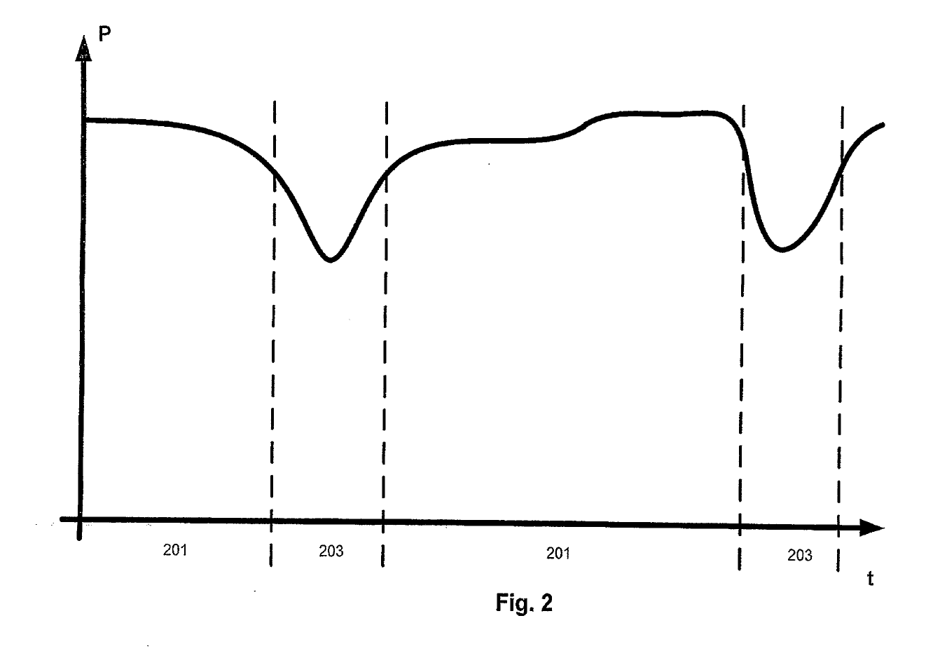

FIG. 2 shows an example of an overall power output of energy sources (100) in the energy network (100) seen over time. In periods 201 there is an approximately even production of energy from the energy sources (100). In certain periods, the production of the energy sources (100) is smaller, such periods being designated low periods (203). Such uneven supply is due to a number of factors, including varying output from the energy sources (100).

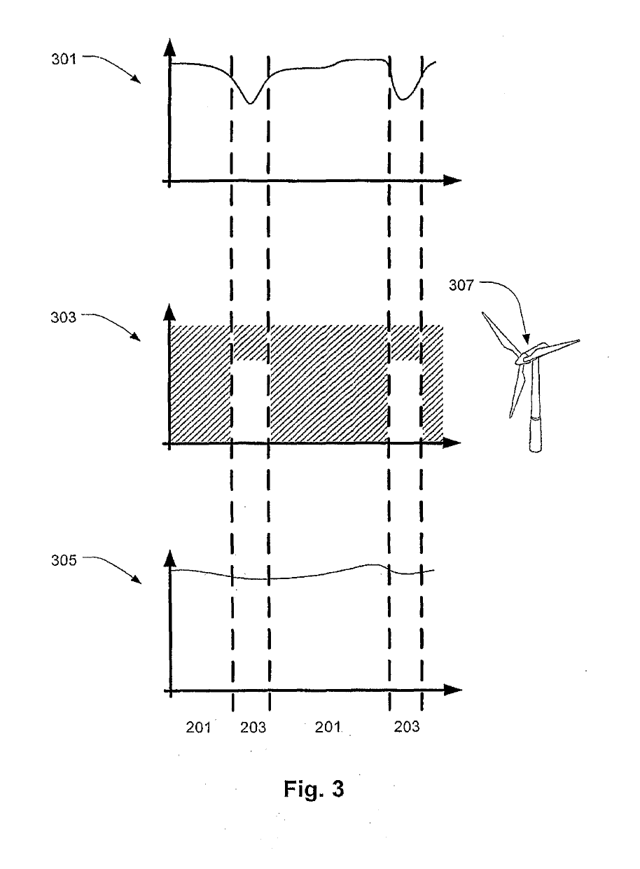

FIG. 3 shows the principle behind a method according to the invention for determining a desired power curve for a wind power plant (307) for being coupled as energy source to an existing power network. The uppermost curve (301) is identical to FIG. 2 and shows the energy production from sources of energy (100) in a power network, but wherein outage of energy production occurs during certain periods (203). In the context of an addition of a further source of energy in the shape of a wind power plant (307) as a supplement to the energy sources that supply the power output 301 it is desired to obtain a more uniform supply of power, and therefore it is desired to add a source of energy that supplies most energy during periods of time (203) when the remaining supply of energy is low. The lowermost curve (305) illustrates production from all sources of energy (100) seen over time following addition of the wind power plant (307).

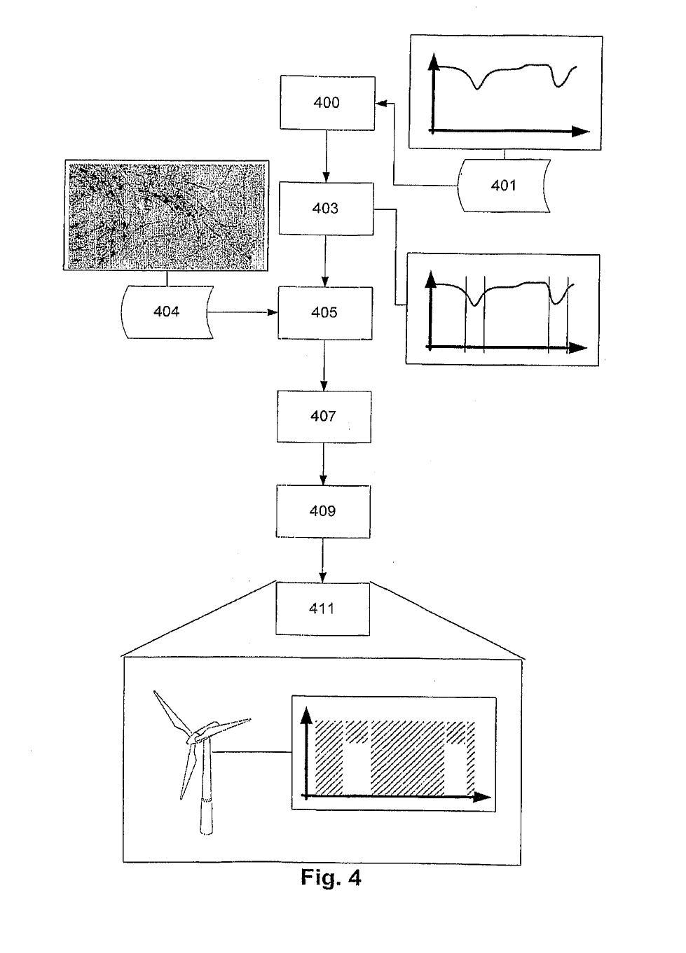

FIG. 4 shows a method of determining a desired power curve for a wind power plant for being coupled to an existing power network. In the first step (400) of the method a history is entered/read for a given period of time, e.g. from a power output log (410). In the next step (403), based on the entered/read history of the power output, periods of low energy production is identified, e.g. on the basis of a specific threshold value. In step (405), a wind and weather history is entered/read for the same period of time as the power output entered in step (400) from a wind and weather log (404). In the subsequent step (407) the entered wind and weather history is identified in the identified periods of low power output. Then, in step (409), characteristics for the wind and weather history in the identified periods of low power output are identified. Based on the characteristics found in step (409), it is possible, in step (411), to design a wind power plant with a power curve such that it is optimised for supplying energy in the low periods; the wind power plant is designed such that the power yield is maximised to the wind and weather characteristics identified in (409).

Wind and weather characteristics may e.g. be wind speed and direction, and other meteorological characteristics that influence the power curve for a wind power plant are temperature, pressure, and ice formation.

Alternatively, one may also log power output data, and when they are below said threshold value, wind and weather data are collected. Thereby only the relevant wind and weather data are read, and thus reading is avoided of data that can be very space-consuming in terms of saving where, however, the data are not to be used anyway.

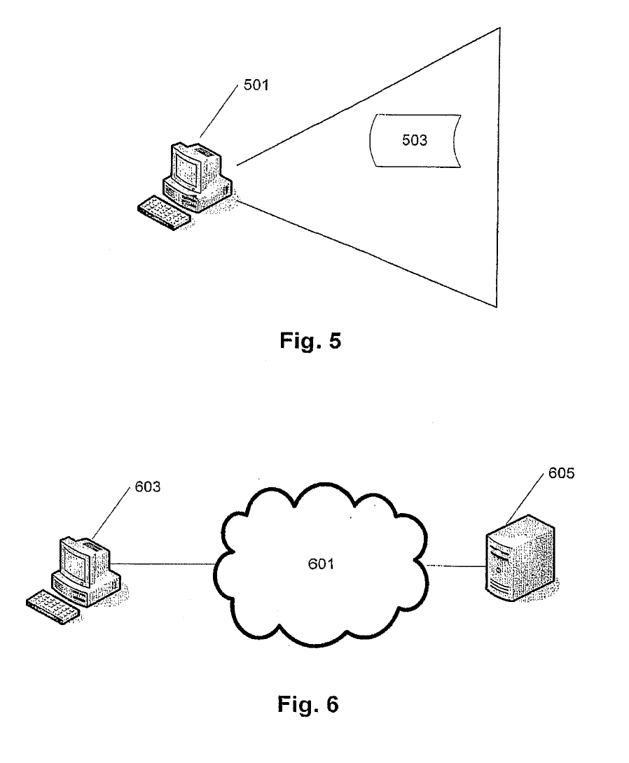

FIG. 5 shows a system for determining a desired power curve for a wind power plant for being coupled to an existing power network. The system comprises a local computer 501 which, based on both power output data and wind and weather data stored in 503, can exercise the method described in the context of FIG. 4.

FIG. 6 shows an alternative embodiment of a system for determining a desired power curve for a wind power plant for being coupled to an existing power network. The system comprises a local computer (603) which, via the internet (601), is connected to a server (605). According to one embodiment, the stored power output data and the wind and weather data can be stored on the server, and via a network, e.g. the internet (601), the computer retrieves data to subsequently exercise the method described in the context of FIG. 4. According to a further embodiment the local computer (603) serves only as a terminal which is able to log onto the server located and handled by a provider. The local computer (603) is able to log on, e.g. via a specific account, and in the context of that, on the basis of data comprising wind and weather data and power output data, to obtain calculations of characteristics for a wind power plant which may be added to a group of existing sources of energy and thereby be used in connection with the designing of the wind power plant.

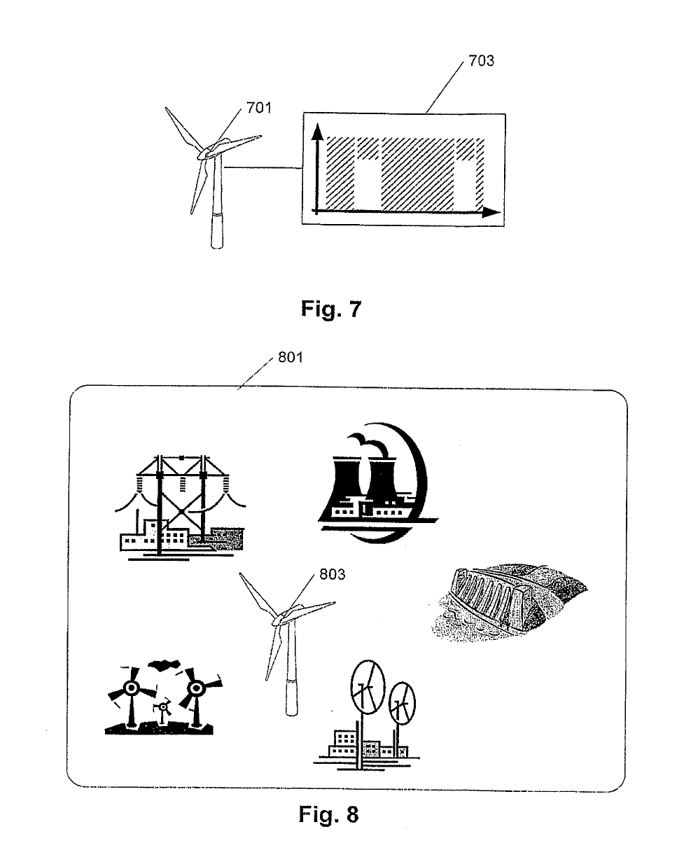

FIG. 7 shows a wind power plant (701) and a determined, desired power curve (703). Based on the found wind and weather characteristics, the wind power plant can be designed such that factors such as location, blade size, blade angulation, etc., are determined in such a way that, precisely during periods with wind and weather characteristics corresponding to the identified periods, the wind power plant provides a maximised yield. The power curve is the power supplied from the wind power plant as a function of the wind speed. Another option could be that, from a group of wind power plants, one chose to locate the plant where the power curve is closest to the desired one.

According to particular embodiments, one could imagine that, as a starting point, it was determined on which geographic position it is desired to arranged the wind power plant, and hence one measures the wind and weather conditions on that position with a view to finding the desired power curve for the wind power plant which is subsequently designed/selected accordingly.

According to a further embodiment, the wind and weather conditions for a number of geographic positions are known, and apart from selection/design of wind power plants, also the geographic position is selected with a view to achieving a given power curve from the wind power plant.

With a view to identification of periods of time with low power output, one could imagine—in one embodiment—that the total power output from the power network for a period of one month is looked upon. The frequency probability is increased when the period is increased.

FIG. 8 shows a group of energy sources 801 comprising a wind power plant 803 and a number of other energy sources where the power curve of the wind power plant is such that power supply is maximised during periods when the total power output from the remaining energy sources of the group is low.

1. A method of determining a desired power curve for a wind power plant for use in connection with the subsequent design and positioning of the wind power plant, where the wind power plant is to be coupled as energy source to a power network comprising a number of energy sources, the method comprising:
determining a power curve relative to the remaining energy sources of the power network to maximize the power output of the wind energy plant during periods of time when the total power output from the remaining energy sources of the power network is low, where wind and weather data for the determined periods of time are used in connection with the determination of the power curve.

2. A method according to claim 1, where wind and weather data are collected for the geographical position where it is intended to deploy a wind power plant.

3. A method according to claim 1, further comprising:
collecting wind and weather data for several geographical positions.

4. A method according to claim 1, further comprising:
determining whether the total power output from the remaining energy sources of the power network is low based on a pre-defined threshold value.

5. A system of determining a desired power curve for a wind power plant for use in connection with subsequent design and positioning of the wind power plant, wherein the wind power plant is to be coupled as energy source to a power network comprising a number of energy sources, said system comprising:
means for measuring and collecting the total power output from the remaining energy sources of the power network as a function of time;
means for identifying periods of time when the total power output from the remaining energy sources of the power network is low;
means for determining a desired power curve based on the identified periods of time.

6. A system according to claim 5, where the system further comprises means for collecting wind and weather data for the determined periods of time.

7. A group of energy sources comprising a wind power plant and a number of remaining energy sources, where a power curve of the wind power plant is such that power supply is maximized during periods of time when the total power output from the remaining sources of energy is low.
